(19) United States
(12) Patent Application Publication
(10) Pub. No.: US 2007/0114525 A1
(43) Pub. Date: May 24, 2007

(54) Display device and manufacturing method

(75) Inventors: Yong-uk Lee, Gyeonggi-so (KR); Mun-pyo Hong, Gyeonggi-do (KR); Bo-sung Kim, Seoul (KR); Joon-hak Oh, Gyeonggi-do (KR); Soo-jin Kim, Gyeonggi-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/604,076

(22) Filed: Nov. 22, 2006

(30) Foreign Application Priority Data
Nov. 22, 2005 (KR) 2005-0112035

(51) Int. Cl. H01L 51/00

(52) U.S. Cl. 257/40

(57) ABSTRACT

Embodiments of a display device comprises an insulating substrate; a source electrode and a drain electrode on the insulating substrate and separated from one another to define a channel region; a wall having one or more openings to expose the channel region, at least a portion of the source electrode, and at least a portion of the drain electrode; and an organic semiconductor layer formed in the one or more openings, the one or more openings comprising a channel part exposing the channel region and an ink guide part extending outward from the channel part. The ink-jet printing process for the display device has an improved processing margin.

### CROSS-REFERENCE TO RELATED APPLICATIONS

This application claims the benefit of Korean Patent Application No.2005-0112035, filed on Nov. 22, 2005, in the Korean Intellectual Property Office, the disclosure of which is incorporated herein by reference.

### BACKGROUND OF THE INVENTION

1. Field of the Invention

The present invention relates to a display device and a manufacturing method thereof, and more particularly, to a display device and a manufacturing method thereof comprising an organic semiconductor layer.

2. Description of the Related Art

A number of types of flat display devices are available; for example, liquid crystal displays (LCDs), organic light emitting diode (OLED) displays, etc.

An LCD comprises an LCD panel having a thin film transistor (TFT) substrate where TFTs are provided, a color filter substrate where color filters are provided, and a liquid crystal layer disposed between the two substrates.

The TFT substrate comprises a plurality of TFTs which are implemented as switching and driving elements to control and drive associated pixels. Each TFT comprises a semiconductor layer, which typically employs amorphous silicon or poly silicon. Recently, organic semiconductor materials have been used for the semiconductor layer.

Organic semiconductor (OSC) materials may be formed at normal temperature and pressure, so that the processing cost may be less than the cost of displays incorporated amorphous silicon or polysilicon semiconductor layers. Because they may be formed at relatively low temperatures, OSC materials may be used for displays using a plastic substrate that is easily affected by heat.

The organic semiconductor may be formed by an ink-jet printing process without the need for coating, exposing and developing processes. A wall is formed to encompass an area where the organic semiconductor is to be disposed. An organic semiconductor solution is jetted to an enclosed area bounded by the wall. A solvent is then removed from the organic semiconductor solution, thereby forming the organic semiconductor.

However, it is difficult to properly control the nozzle used to jet the organic semiconductor solution to the enclosed areas for the TFTs, since the areas are very small. Thus, the organic semiconductor layer may not be patterned to a desired shape, or its thickness may be different for different pixels, so that characteristics of the organic semiconductor are not uniform.

### SUMMARY OF THE INVENTION

Accordingly, it is an aspect of the present invention to provide a display device in which the processing margin of the ink-jet printing process is improved.

Another aspect of the present invention is to provide a manufacturing method of a display device which improves the processing margin of the ink-jet printing process.

The foregoing and/or other aspects of the present invention are also achieved by providing a display device comprising: an insulating substrate; a source electrode and a drain electrode formed on the insulating substrate and separated from one another to define a channel region; a wall having one or more openings to expose the channel region, at least a portion of the source electrode, and at least a portion of the drain electrode; and an organic semiconductor layer formed in the one or more openings, the one or more openings comprising a channel part exposing the channel region and an ink guide part extending outward from the channel part.

According to an embodiment of the present invention, the source electrode and the drain electrode comprise one or more materials selected from the group consisting of ITO, IZO, Al, Cr, Mo, Au, Pt, Pd, Cu and AlNd.

According to an embodiment of the present invention, the organic semiconductor layer comprises at least one material selected from the group consisting of a derivative including substituent of tetracene or pentacene; 4˜8 oligothiopene connected to 2, 5 position of thiopene ring; perylenetetracarboxilic dianhidride or an imide derivative thereof; naphthalenetetracarboxilic dianhydride or an imide derivative thereof; metallized pthalocyanine or a halogenated derivatives thereof, or perylene, coroene or derivatives including substituents thereof; co-oligomer or co-polymer of thienylene and vinylene; thiopene; perylene or coroene, or derivatives including substituents thereof; and derivatives including one or more hydrocarbon chains of 1˜30 carbons to aromatic or heteroaromatic ring of the aforementioned materials.

According to an embodiment of the present invention, the organic semiconductor layer is formed using an ink-jet process.

According to an embodiment of the present invention, the display device further comprises a gate wire and a data wire on the insulating substrate, wherein the gate wire and the data wire cross each other to define a pixel, and wherein the pixel includes an active region configured to generate an image part and a non-active region not configured to generate an image part, and wherein the wall includes a portion formed on the active region of the pixel and a portion formed on the non-active region of the pixel.

According to an embodiment of the present invention, the channel part of the one or more openings at least partially overlaps with at least one of the active region of the pixel and the non-active region of the pixel.

According to an embodiment of the present invention, the ink guide part of the one or more openings at least partially overlaps with at least one of the active region of the pixel and the non-active region of the pixel.

According to an embodiment of the present invention, a portion of the wall is positioned in an overlap region at least partially overlapping with at least one of the gate wire and the data wire.

According to an embodiment of the present invention, at least a portion of the ink guide part overlaps with at least one of the gate wire and the data wire.

According to an embodiment of the present invention, at least a portion of the wall is disposed at an intersection of the gate wire and the data wire.

According to an embodiment of the present invention, the ink guide part comprises a plurality of sub-guide parts extending radially from the channel part, and wherein at least one of the sub-guide parts extends to the overlap region.

According to an embodiment of the present invention, the ink guide part comprises a first sub-guide part extending from the channel part and a second sub-guide part crossing the first sub-guide part, and wherein at least one of the first sub-guide part and the second sub-guide part is extended to the overlap region.

According to an embodiment of the present invention, the display device further comprises a data wire disposed between the insulating substrate and the source electrode and between the insulating substrate and the drain electrode; a buffer layer covering the data wire; a gate wire disposed on the buffer layer and positioned corresponding to the organic semiconductor layer, the gate wire comprising a gate line; and a gate insulating layer covering the gate wire.

According to an embodiment of the present invention, the display device further comprises a passivation layer covering the organic semiconductor layer.

According to an embodiment of the present invention, the gate insulating layer comprises a lower layer and an upper layer, the lower layer is an inorganic layer, and the upper layer is an organic layer.

The foregoing and/or other aspects of the present invention are also achieved by providing a manufacturing method of a display device comprising: providing an insulating substrate; forming a source electrode and a drain electrode on the insulating substrate, the source electrode and the drain electrode separated from one another to define a channel region; forming a wall having one or more openings to expose the channel region, at least a portion of the source electrode, and at least a portion of the drain electrode; and forming an organic semiconductor layer by jetting an organic semiconductor solution in the one or more openings, wherein the one or more openings comprise a channel part exposing the channel region and an ink guide part extending outward from the channel part.

According to an embodiment of the present invention, the manufacturing method of the display device further comprises, before forming the source electrode and the drain electrode, forming a gate wire and a data wire on the insulating substrate, where the gate wire and the data wire cross one another to define a pixel and are insulated from one another, wherein the pixel includes an active region configured to generate an image part and a non-active region not configured to generate an image part, and wherein the wall includes a portion formed on the active region of the pixel and a portion formed on the non-active region of the pixel.

According to an embodiment of the present invention, the organic semiconductor solution is jetted to the non-active region of the pixel.

According to an embodiment of the present invention, the ink guide part at least partially overlaps with at least one of the active region of the pixel and the non-active region of the pixel.

According to an embodiment of the present invention, the organic semiconductor solution is jetted to the ink guide part and at least partially flows into the channel part.

### BRIEF DESCRIPTION OF THE DRAWINGS

The above and/or other aspects and advantages of the present invention will become apparent and more readily appreciated from the following description of the exemplary embodiments, taken in conjunction with the accompanying drawings of which:

FIG. 1 is an arrangement view of a TFT substrate according to a first embodiment of the present invention;

FIG. 2 is a sectional view, taken along line □-□ in FIG. 1;

FIG. 3 illustrates a wall according to the first embodiment of the present invention;

FIG. 4 illustrates a wall according to a second embodiment of the present invention;

FIG. 5 illustrates a wall according to a third embodiment of the present invention;

FIG. 6 illustrates a wall according to a fourth embodiment of the present invention; and

FIGS. 7A and 7B are plan views to illustrate a manufacturing method of a display device according to the present invention.

### DETAILED DESCRIPTION OF THE PREFERRED EMBODIMENT

Reference will now be made in detail to exemplary embodiments of the present invention, examples of which are illustrated in the accompanying drawings, wherein like reference numerals refer to like elements throughout. In the drawings, the thickness of layers, films, and regions are exaggerated for clarity. The embodiments are described below in order to explain the present invention by referring to the figures, however, the exemplary embodiments and figures are only illustrative of the present invention, and not intended to limit the scope of the present invention.

In the following description, if a layer is said to be formed ‘on’ another layer, then one or more intervening layers may be disposed between the two layers, or the two layers may be in direct contact with each other. In other words, it will be understood that when an element such as a layer, film, region, or substrate is referred to as being “on” another element, it can be directly on the other element or intervening elements may also be present. If an element is referred to as being “directly on,” no intervening elements are present.

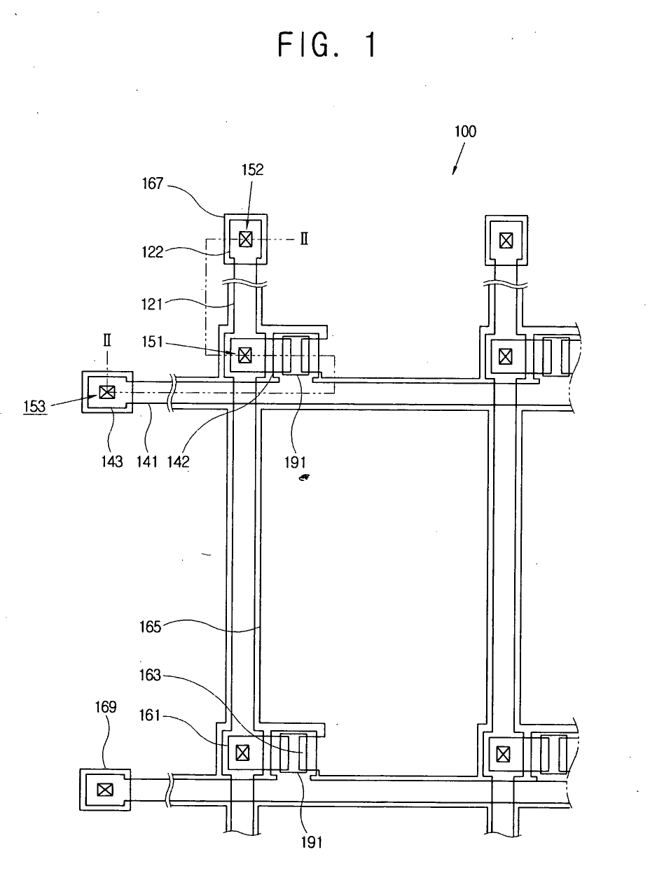

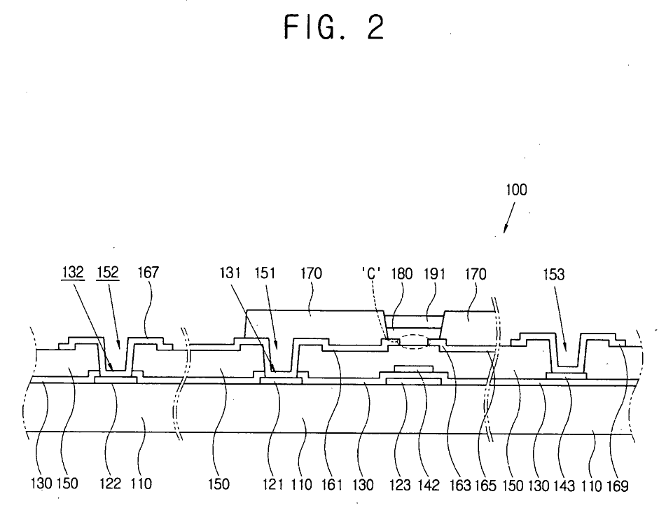

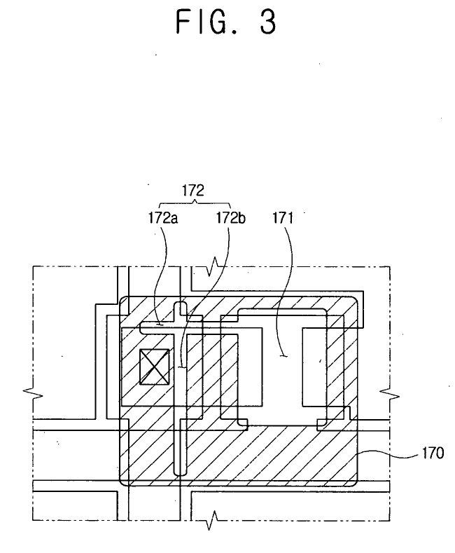

FIG. 1 is an arrangement view of a TFT substrate according to a first embodiment of the present invention, FIG. 2 is a sectional view, taken along line □-□ of FIG. 1, and FIG. 3 illustrates a wall according to the first embodiment of the present invention.

As shown in FIGS. 1 to 3, a TFT substrate 100 according to embodiments of the present invention comprises an insulating substrate 110, a data wire (including elements 121, 122 and 123) formed on the insulating substrate 110, a buffer layer 130 formed on the data wire (121, 122 and 123), a gate wire (including elements 141, 142 and 143) formed on the buffer layer 130, a gate insulating layer 150 formed on the gate wire (141, 142 and 143), a transparent electrode layer (including elements 161, 163 and 165) formed on the gate insulating layer 150, a wall 170 comprising openings 171 and 172 to expose a channel region C formed between a source electrode 161 and a drain electrode 163, an organic semiconductor layer 180 formed in the openings 171 and 172, and a passivation layer 191 formed on the organic semiconductor layer 180.

The insulating substrate 110 comprises glass or plastic. If the insulating substrate 110 is made of plastic, the TFT substrate 100 may have good flexibility, but the insulating substrate 110 is easily affected by heat. Implementing an organic semiconductor layer 180 as disclosed herein allows for easy use of plastic material in the insulating substrate 110, since the organic semiconductor layer 180 is formed at normal temperature and pressure. The plastic material may comprise polycarbonate, polyimide, polyethersulfone (PES), polyaryrate (PAR), polyethylenenaphthalate (PEN), Polyethyleneterephthalate (PET) or other appropriate plastic material.

The data wire (121, 122 and 123) is formed on the insulating substrate 110. The data wire (121, 122 and 123) comprises a data line 121 extending in one direction on the insulating substrate 110, a data pad 122 provided at an end of the data line 121 to receive a driving or a control signal from the outside, and a light shield layer 123 formed at a position corresponding to a gate electrode 142 to cover the organic semiconductor layer 180. In some embodiments, the gate electrode 142 functions as a light shield layer, so that the light shield layer 123 may be omitted. The data pad 122 receives the driving and the control signals from outside the TFT to apply them to the data line 121. In some embodiments, the data wire (121, 122 and 123) comprises an inexpensive conductive material, such as at least one of aluminum (Al), chrome (Cr), molybdenum (Mo), neodymium (Nd), gold (Au), platinum (Pt) and palladium (Pd). The data wire (121, 122 and 123) may have a single-layer structure or a multi-layer structure which comprises at least one of the above-mentioned materials.

In some embodiments of the present invention, the data wire (121, 122 and 123) is formed first, and then the buffer layer 130 is formed thereon so as to protect a first and a second gate insulating layers 150 and 155 and the organic semiconductor layer 180 from chemical materials used while forming the data wire (121, 122 and 123). The buffer layer 130 may prevent deterioration of characteristics of the organic semiconductor layer 180 that may be caused by the chemical materials.

The buffer layer 130 is disposed on the insulating substrate 110 and covers the data wire (121, 122 and 123). The buffer layer 130 insulates the data wire (121, 122 and 123) and the gate wire (141, 142, and 143) from each other. Buffer layer 130 comprises an inorganic layer comprising an inorganic material, such as silicon nitride (SiNx) or silicon oxide (SiOx), or an organic layer comprising an organic material. The organic material used for the buffer layer 130 may comprise at least one of acrylic resin, polyvinyl alcohol, benzocyclobutene, polyvinylphenol resin, fluoric polymer and polystyrene resin. Alternatively, the buffer layer 130 may have a double-layer structure comprising an inorganic layer and an organic layer. The buffer layer 130 comprises buffer layer contact holes 131 and 132 exposing the data line 121 and the data pad 122 therethrough.

The buffer layer 130 may minimize deterioration of the characteristics of the organic semiconductor layer 180. The material of organic semiconductor layer 180 is easily affected by the chemical materials or plasma used for the data wire (121, 122 and 123), which remains and flows into a gap or an interface between the buffer layer contact holes 131 and 132 and insulating contact holes 151, 152 and 153. Moreover, the buffer layer 130 prevents the light shield layer 123 from functioning as a floating electrode.

The gate wire (141, 142 and 143) is formed on the buffer layer 130. The gate wire (141, 142 and 143) comprises a gate line 141 crossing and insulated from the data line 121 to define a pixel, a gate pad 143 provided at an end of the gate line 141 to receive a driving or a control signal from the outside, and a gate electrode 142 branched from the gate line 141 and formed at a position corresponding to the position of organic semiconductor layer 180. The gate pad 143 receives the driving and the control signals turning the TFTs on/off from the outside TFT substrate 100 and transmits them to the gate electrode 142 through the gate line 141. The gate wire (141, 142 and 143), like the data wire (121, 122 and 123), comprises at least one of Al, Cr, Mo, Nd, Au, Pt and Pd, and has a single-layer structure or a multi-layer structure.

The gate insulating layer 150 is formed on the gate wire (141, 142 and 143). The gate insulating layer 150 insulates the data wire (121, 122 and 123) and the gate wire (141, 142 and 143) from each other and prevents impurities from flowing into the organic semiconductor layer 180. The gate insulating layer 150 comprises at least one of SiOx and SiNx, which have excellent durability. Further, the gate insulating layer 150 may comprise an organic layer or may have a double-layer structure comprising an inorganic layer and an organic layer.

The gate insulating layer 150 comprises the insulating contact hole 153 exposing the gate pad 143 and the insulating contact holes 151 and 152 exposing connector members 144 and 145.

The transparent electrode layer (including elements 161, 163, 165, 167 and 169) is formed on the gate insulating layer 150. The transparent electrode layer (161, 163, 165, 167 and 169) is connected to the data line 121 through the insulating layer contact hole 151 and comprises the source electrode 161 at least partially in contact with the organic semiconductor layer 180, the drain electrode 163 separated from the source electrode 161, the organic semiconductor layer 180 being disposed therebetween, and a pixel electrode 165 connected to the drain electrode 163 to be formed in a pixel region. Furthermore, the transparent electrode layer further comprises a data pad contact member 167 covering the data pad 122 exposed through the insulating layer contact hole 152 and a gate pad contact member 169 covering the gate pad 143 exposed through the insulating layer contact hole 153. The transparent electrode layer (161, 163, 165, 167 and 169) comprises a transparent conductive material, such as indium tin oxide (ITO) or indium zinc oxide (IZO). Alternatively, the source electrode 161 and the drain electrode 163 may comprise at least one of Al, Cr, Mo, Au, Pt, Pd, Cu and AlNd, which have high work function. The source electrode 161 is physically and electrically connected to the data line 121 through the insulating layer contact hole 151 to receive an image signal. The TFTs include a drain electrode 163 and an associated source electrode 161 separated from one another, a gate electrode 143 being disposed therebetween and proximate to the channel region. The TFTs function as switching and driving elements controlling and driving operation of each pixel electrode 165.

As shown in FIG. 3, the wall 170 comprises openings 171 and 172 exposing a channel region C, at least a portion of the source electrode 161, and at least a portion of the drain electrode 163. Here, a pixel comprises an active region where an image is formed and a non-active region where an image is not formed. The wall 170 according to the illustrated embodiment of the present invention includes portions over the active region and the non-active region. In some embodiments, at least a portion of the wall 170 may be disposed to overlap with at least one of the data wire (121, 122 and 123) and the gate wire (141, 142 and 143). In particular, a portion of the wall 170 may be disposed proximate an intersection of the data wire (121, 122 and 123) and the gate wire (141, 142 and 143). The wall 170 acts as a barrier to flow of the organic semiconductor solution to other portions of the substrate. Thus, using wall 170, the organic semiconductor solution provided using the ink jet (or similar) process is disposed in the openings 171 and 172 to form an organic TFT. Solvent is removed from the organic semiconductor solution jetted in the openings 171 and 172 to form the organic semiconductor.

However, the openings 171 and 172 of the wall 170 are very small, and thus it is difficult to control the nozzle used to jet the organic semiconductor solution so that its position corresponds correctly to the openings 171 and 172. In other words, the processing margin of the ink-jet printing process is low, so that the jetted organic semiconductor solution may not be disposed only in the openings 171 and 172, but may be disposed on the wall 170 or the pixel. Thus, the organic semiconductor layer 180 may not be patterned in a desired shape, or its thickness may be different on different pixels, so that characteristics of the organic TFT (OTFT) are not uniform.

To decrease this problem, the wall 170 may be surface-treated so that the organic semiconductor solution jetted on the wall 170 may easily flow into the openings 171 and 172 so that the organic semiconductor is self-patterned. That is, a surface of the wall 170 is treated (e.g., with plasma) to increase its water repellency and oil repellency with respect to the organic semiconductor solution jetted. As a result, the semiconductor solution jetted on the wall 170 flows into the openings 171 and 172. In some embodiments, the plasma treatment comprises a CF₄/O₂ plasma treatment.

The wall 170 may comprise photoresist having thermal resistance and solvent-resisting properties, such as acrylic resin, polyimide resin, etc.; an inorganic material, such as SiO₂ and TiO₂; or a double-layer structure having an organic layer and an inorganic layer. In some embodiments, the wall 170 may comprise fluoric polymer. In this case, wall 170 repels water and oil due to characteristics of the material.

Thus, in embodiments in which wall 170 has enhanced water and/or oil repellency, the organic semiconductor solution jetted on the wall 170 that extends at least partially on the openings 171 and 172 flows into the openings 171 and 172, so that the organic semiconductor solution is self-patterned while being dried. However, the organic semiconductor solution that does not extend on the openings 171 and 172 may not flow into the openings 171 and 172.

Since the organic semiconductor solution is easily self-patterned if it at least partially extends on the openings 171 and 172 (that is, if at least part of a body of jetted solution extends to one or both of openings 171 and 172), the opening (an ink guide part) 172 is formed to extend outward from opening (a channel part) 171 exposing the channel region C in the present disclosure. As shown in FIG. 3, the wall 170 according to the present disclosure comprises the opening 171, which is a channel part expositing the channel region C, as well as opening 172, which is an ink guide part extending outward from the channel part 171.

The channel part 171 and the ink guide part 172 may at least partially overlap with at least one of the active region and the non-active region. In particular, the channel part 171 illustrated in this embodiment is mainly formed in the active region, and the ink guide part 172 is mainly formed in the non-active region. In order to improve the processing margin of the ink-jet printing, the size of the wall 170 is increased to have an overlap area with at least one of the data wire (121, 122 and 123) and the gate wire (141, 142 and 143), and the ink guide part 172 is extended to the overlap area.

The ink guide part 172 according to the first embodiment of the present invention comprises a first sub-guide part 172a extending outward from the channel part 171 and a second sub-guide part 172b crossing the first sub-guide part 172a. The first and the second sub-guide parts 172a and 172b overlap with at least one of the data wire (121, 122 and 123) and the gate wire (141, 142 and 143). Since the size of the wall 170 is increased, the processing margin of the ink-jet printing is improved. The size of wall 170 is increased, and the wall 170 overlaps with the data wire (121, 122 and 123) and the gate wire (141, 142 and 143). This configuration prevents reduction of aperture ratio due to the increased size of the wall 170. Further, increasing the size of the wall 170 and implementing the ink guide part 172 allows the organic semiconductor solution to be jetted more accurately on the openings 171 and 172. As a result, the organic semiconductor is more easily self-patterned, and the processing margin of the ink-jet printing is improved.

The organic semiconductor layer 180 is formed in the openings 171 and 172. The semiconductor layer 180 covers the channel region C and, at least partially, overlaps with the source electrode 161 and the drain electrode 163. In some embodiments, the organic semiconductor layer 180 is one of a derivative including substituent of tetracene or pentacene; 4˜8 oligothiopene connected to 2, 5 position of thiopene ring; perylenetetracarboxilic dianhidride or an imide derivative thereof; naphthalenetetracarboxilic dianhydride or an imide derivative thereof; metallized pthalocyanine or a halogenated derivatives thereof, or perylene, coroene or derivatives including substituents thereof; co-oligomer or co-polymer of thienylene and vinylene; thiopene; perylene or coroene, or derivatives including substituents thereof; and derivatives including one or more hydrocarbon chains of 1˜30 carbons to aromatic or heteroaromatic ring of the aforementioned materials. In addition, the semiconductor layer 180 may comprise a known organic semiconductor material. The organic semiconductor layer 180 is formed by jetting the organic semiconductor solution in the openings 171 and 172 and removing the solvent from the solution.

A passivation layer 191 is formed on the organic semiconductor layer 180. The passivation layer 191 has a single-layer structure, but, unlike the drawings, may have a multi-layer (e.g., double-layer) structure. In some embodiments, the passivation layer 191 is a material such as fluoric polymer or polyvinyl alcohol (PVA) with characteristics that reduce or prevent the organic semiconductor layer 180 from deteriorating.

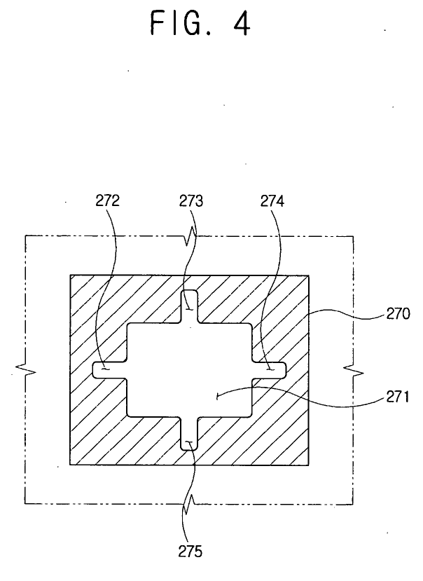

Hereinafter, a second embodiment through a fourth embodiment of the present invention will be described with reference to FIGS. 4 through 6. It should be noted that the following description emphasizes features different from those of the first embodiment, and discussion of similar features may be omitted.

FIG. 4 schematically illustrates a wall 270 according to a second embodiment of the present invention. As shown in FIG. 4, the wall 270 according to the second embodiment comprises an opening including a channel part 271 exposing a channel region, at least a portion of a source electrode and at least a portion of a drain electrode, and an ink guide part 272, 273, 274 and 275 extending radially from the channel part 271. The ink guide part 272, 273, 274 and 275 comprises a first sub-guide part 272, a second sub-guide part 273, a third sub-guide part 274 and a fourth sub-guide part 275. At least one of the first, the second, the third and the fourth sub-guide parts 272, 273, 274 and 275 extends to an overlap area of the wall 270 and the gate wire and the data wire.

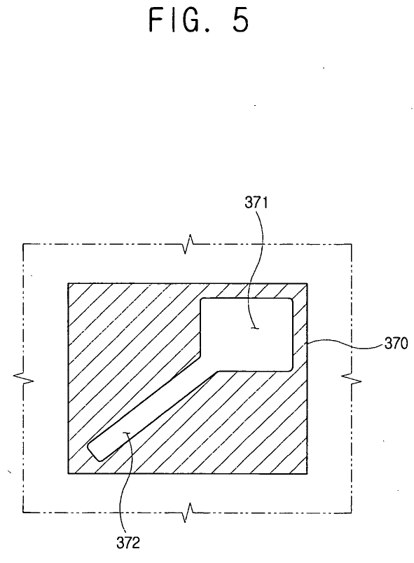

FIG. 5 schematically illustrates a wall according to a third embodiment of the present invention. As shown in FIG. 5, the wall 370 comprises an opening having a channel part 371 exposing a channel region, at least a portion of a source electrode and at least a portion of a drain electrode, and an ink guide part 372 extending outward from the channel part 371.

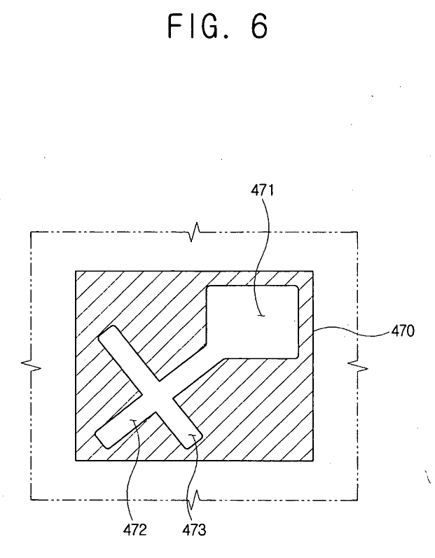

FIG. 6 schematically illustrates a wall according to a fourth embodiment of the present invention. As shown in FIG. 6, the wall 470 comprises an opening with a channel part 471 positioned in one corner region of the wall 470 and an ink guide part 472 and 473 positioned in another corner region of the wall 470. The ink guide part 472 and 473 comprises a first sub-guide part 472 connected to the channel part 471 and a second sub-guide part 473 crossing the first sub-guide part 472.

The aforementioned first through fourth embodiments are not limited to the above descriptions, but may vary with different configurations. For example, more or fewer sub-guide parts may be used, and their general shape and positioning may be different than illustrated.

The wall according to the present invention may be employed in the fabrication of display devices such as liquid crystal displays (LCDs), organic light emitting diode (OLED) displays, and electro phoretic indication displays.

An OLED display is a self light-emitting device using an organic material, which emits light in response to receiving an electric signal. OLED displays generally include a number of layers, including a cathode layer (pixel electrode), a hole-injection layer, a hole-transfer layer, a light-emitting layer, an electron-transfer layer, an electron-injection layer, and an anode layer (counter electrode). A drain electrode on a TFT substrate (e.g., as illustrated in FIG. 2) is electrically connected to the cathode layer to apply a data signal.

An electro phoretic indication display is a flat panel display generally used for e-book (electronic book) applications. An electro phoretic indication display comprises a first substrate where a first electrode and TFTs are formed, a second substrate where a second electrode is formed, a fluid disposed between the first substrate and the second substrate, and charged particles dispersed in the fluid. The charged particles are either positive or negative, and either black or white. If voltage is applied to the first and second electrodes (which are positioned facing one another), an electric field is generated between them based on the potential difference. The charged particles transfer up and down towards an electrode having a polarity opposite to the charge of the particle. Accordingly, an observer recognizes light incident from the outside and reflected in the charged particles. If the charged particles transfer up close to the observer, he/she recognizes colors of the charged particles more intensely. If the charged particles transfer down, the observer recognizes colors of the charged particles less intensely. Accordingly, the electro phoretic indication display displays an image.

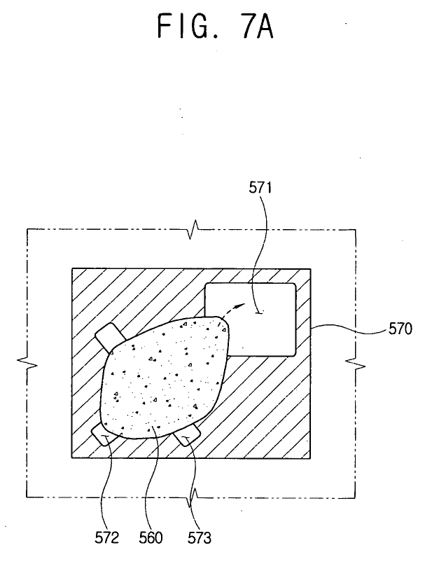

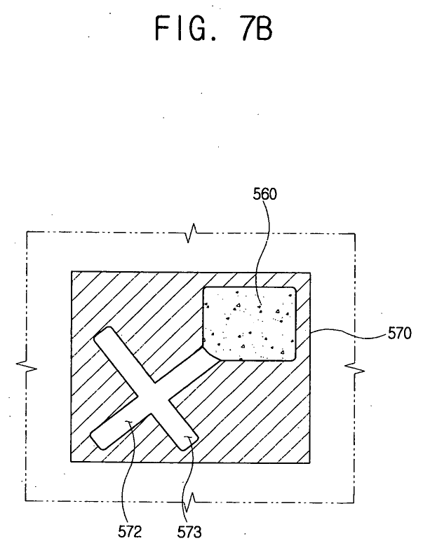

Hereinafter, a manufacturing method of a display device according to embodiments of the present invention will be briefly described, with reference to FIGS. 7A and 7B. In the following description, distinctive features of the present disclosure will be discussed more fully, while other features may not be discussed, since they are generally known to a person of ordinary skill in the art and examples of other features are described in prior art.

As with prior art systems, a data wire and a gate wire are formed on an insulating substrate. The data wire and the gate wire are insulated from one another and cross each other to define a pixel. The pixel comprises an active region where an image is formed and a non-active region where the image is not formed. A buffer layer is interposed between the data wire and the gate wire.

A gate insulating layer is formed on the gate wire, and a source electrode and a drain electrode are formed. The source electrode and drain electrode are separated from one another to define a channel region on the gate insulating layer. A wall 570 is then formed. The wall 570 comprises openings 571, 572 and 573 exposing the channel region, a portion of the source electrode and a portion of the drain electrode. The wall 570 is extended on the active region and the non-active region. The openings 571, 572 and 573 comprises a channel part 571 exposing the channel region and an ink guide part 572 and 573 extending outward from the channel part 571. The openings 571, 572 and 573 may be formed using a mask and exposing and developing processes. The openings may have various shapes, such as those shown in FIGS. 3 through 6. Thereafter, the wall 570 is treated with O₂/CF₄ plasma so that its surface has water repellency and oil repellency with respect to an organic semiconductor solution. An organic semiconductor solution 560 is jetted with a nozzle in the openings 571, 572 and 573. The organic semiconductor solution 560 is jetted to the openings 571, 572 and 573 in the non-active region, to reduce splash to the active region.

Preferably, the organic semiconductor solution 560 is jetted to the channel part 571 where a channel is formed. However, it may be jetted on the wall 570 as shown in FIG. 7A, since it is difficult to control the position of the nozzle, and also because the channel part 571 has a small area. However, the wall 570 comprises the ink guide part 572 and 573, so that the organic semiconductor solution 560 may extend on the ink guide part 572 and 573 of the opening when jetted in an area outside the channel part 571. The size of wall 570 is increased, according to embodiments of the present invention, and overlaps with a portion of the gate wire and a portion of the data wire in an overlap area. The ink guide part 572 and 573 of the opening extends to the overlap area, thus increasing the possibility that the organic semiconductor solution 560 is jetted in the channel part 571 and the ink guide part 572 and 573 of the opening. As shown in FIG. 7B, the organic semiconductor solution 560 jetted to extend on the ink guide part 572 and 573 of the opening is easily self-patterned to flow into the channel part 571 along the ink guide part 572 and 573, since the surface of the wall 570 has water repellency and oil repellency. The solvent is then removed from the organic semiconductor solution 560, thereby completing an organic semiconductor layer. Accordingly, the manufacturing method of the display device can improve the processing margin of ink-jet printing.

As described above, the present disclosure provides a display device which has an improved processing margin of an ink-jet printing process.

Also, the present disclosure provides a manufacturing method of a display device which improves a processing margin of an ink-jet printing process.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A display device comprising:
an insulating substrate;
a source electrode and a drain electrode formed on the insulating substrate and separated from one another to define a channel region;
a wall having one or more openings to expose the channel region, at least a portion of the source electrode, and at least a portion of the drain electrode; and
an organic semiconductor layer formed in the one or more openings,
wherein the one or more openings comprise a channel part exposing the channel region and an ink guide part extending outward from the channel part.

2. The display device according to claim 1, wherein the source electrode and the drain electrode comprise at least one material selected from the group consisting of ITO, IZO, Al, Cr, Mo, Au, Pt, Pd, Cu and AlNd.

3. The display device according to claim 1, wherein the organic semiconductor layer comprises at least one material selected from the group consisting of a derivative including substituent of tetracene or pentacene; 4˜8 oligothiopene connected to 2, 5 position of thiopene ring; perylenetetracarboxilic dianhidride or an imide derivative thereof; naphthalenetetracarboxilic dianhydride or an imide derivative thereof; metallized pthalocyanine or a halogenated derivatives thereof, or perylene, coroene or derivatives including substituents thereof; co-oligomer or co-polymer of thienylene and vinylene; thiopene; perylene or coroene, or derivatives including substituents thereof; and derivatives including one or more hydrocarbon chains of 1˜30 carbons to aromatic or heteroaromatic ring of the aforementioned materials.

4. The display device according to claim 3, wherein the organic semiconductor layer is formed using an ink-jet process.

5. The display device according to claim 1, further comprising a gate wire and a data wire on the insulating substrate, wherein the gate wire and the data wire cross each other to define a pixel, and wherein the pixel includes an active region configured to generate an image part and a non-active region not configured to generate an image part, and
wherein the wall includes a portion formed on the active region of the pixel and a portion formed on the non-active region of the pixel.

6. The display device according to claim 5, wherein the channel part of the one or more openings at least partially overlaps with at least one of the active region of the pixel and the non-active region of the pixel.

7. The display device according to claim 5, wherein the ink guide part of the one or more openings at least partially overlaps with at least one of the active region of the pixel and the non-active region of the pixel.

8. The display device according to claim 5, wherein a portion of the wall is positioned in an overlap region at least partially overlapping with at least one of the gate wire and the data wire.

9. The display device according to claim 5, wherein at least a portion of the ink guide part overlaps with at least one of the gate wire and the data wire.

10. The display device according to claim 5, wherein at least a portion of the wall is disposed at an intersection of the gate wire and the data wire.

11. The display device according to claim 8, wherein the ink guide part comprises a plurality of sub-guide parts extending radially from the channel part, and wherein at least one of the sub-guide parts extends to the overlap region.

12. The display device according to claim 8, wherein the ink guide part comprises a first sub-guide part extending from the channel part and a second sub-guide part crossing the first sub-guide part, and wherein at least one of the first sub-guide part and the second sub-guide part is extends to the overlap region.

13. The display device according to claim 1, further comprising,
a data wire disposed between the insulating substrate and the source electrode and between the insulating substrate and the drain electrode;
a buffer layer covering the data wire;
a gate wire disposed on the buffer layer and positioned corresponding to the organic semiconductor layer, the gate wire comprising a gate line; and
a gate insulating layer covering the gate wire.

14. The display device according to claim 13, further comprising a passivation layer covering the organic semiconductor layer.

15. The display device according to claim 13, wherein the gate insulating layer comprises a lower layer and an upper layer, and wherein the lower layer is an inorganic layer, and the upper layer is an organic layer.

16. A manufacturing method of a display device comprising:
providing an insulating substrate;
forming a source electrode and a drain electrode on the insulating substrate, the source electrode and the drain electrode separated from one another to define a channel region;
forming a wall having one or more openings to expose the channel region, at least a portion of the source electrode, and at least a portion of the drain electrode; and
forming an organic semiconductor layer by jetting an organic semiconductor solution in the one or more openings,
wherein the one or more openings comprise a channel part exposing the channel region and an ink guide part extending outward from the channel part.

17. The manufacturing method of the display device according to claim 16, further comprising, before forming the source electrode and the drain electrode, forming a gate wire and a data wire on the insulating substrate, where the gate wire and the data wire cross one another to define a pixel and are insulated from one another, wherein the pixel includes an active region configured to generate an image part and a non-active region not configured to generate an image part, and
wherein the wall includes a portion formed on the active region of the pixel and and a portion formed on the non-active region of the pixel.

18. The manufacturing method of the display device according to claim 17, wherein the organic semiconductor solution is jetted to the non-active region of the pixel.

19. The manufacturing method of the display device according to claim 17, wherein the ink guide part at least partially overlaps with at least one of the active region of the pixel and the non-active region of the pixel.

20. The manufacturing method of the display device according to claim 19, wherein the organic semiconductor solution is jetted to the ink guide part and at least partially flows into the channel part.
